(19) United States
(12) Patent Application Publication
(10) Pub. No.: US 2026/0332002 A1
(43) Pub. Date: Oct. 22, 2026

(54) ELECTRIC TOOL

(71) Applicant: Panasonic Electric Works Co., Ltd., Osaka (JP)

(72) Inventors: Naoki TSUJIMOTO, Mie (JP); Kotaro MOMOEDA, Osaka (JP); Kohei KOSAKA, Mie (JP); Masanobu NONAMI, Mie (JP)

(21) Appl. No.: 19/116,743

(22) PCT Filed: Oct. 3, 2023
(86) PCT No.: PCT/JP2023/036018

§ 371 Date: Mar. 28, 2025

(30) Foreign Application Priority Data
Oct. 14, 2022 (JP) 2022-165832

(51) Int. Cl. H02K 11/00; H02K 5/04; H02K 7/14; H05K 1/181; H05K 7/14

(52) U.S. Cl. CPC H02K 11/0094; H02K 5/04; H02K 7/145; H05K 1/181; H05K 7/1427; H05K 2201/10015; H05K 2201/10189; H05K 2201/10356

(57) ABSTRACT

An electric tool includes a motor, a plurality of switch elements, a cylindrical capacitor, a circuit board and a housing. The circuit board mounts the capacitor thereon and is fixed to overlap with at least a part of the motor when viewed in an axial direction defined with respect to a rotary shaft of the motor. The circuit board has a base portion having a shape of plate and a protruding portion having a shape of a plate. The protruding portion protrudes from an end part of the base portion in a predetermined direction. The capacitor is arranged on the protruding portion to overlap with at least a part of the motor when viewed in a protruding direction that is the predetermined direction.

### TECHNICAL FIELD

The present disclosure generally relates to an electric tool, and more particularly relates to an electric tool including a motor.

### BACKGROUND ART

Patent Literature 1 discloses a controller for controlling a motor used for an electric impact screwdriver. The controller for the motor includes an inverter circuit, a gate driver circuit, an arithmetic circuit, a speed instructing circuit, and a torque control switch. The inverter circuit outputs a drive signal to a brushless DC motor that drives an electric tool such as an electric screwdriver or an electric impact screwdriver. The gate driver circuit controls the inverter circuit. The arithmetic circuit performs pulse width modulation (PWM) control on the gate driver circuit. The speed instructing circuit outputs a speed instruction signal to the arithmetic circuit in response to a signal supplied from a trigger switch for controlling the electric tool. The torque control switch defines a preset torque value for the motor to prevent the motor not to rotate with torque equal to or greater than the preset torque value. The arithmetic circuit performs the PWM control so that the motor does not rotate with torque equal to or greater than the preset torque value when the torque control switch is ON.

The electric impact screwdriver disclosed in Patent Literature 1 includes a capacitor in order to stabilize the voltage applied to a plurality of switch elements. However, in general, a capacitor will be directly mounted on a circuit board. Therefore, a housing that houses the capacitor will have an increased size when a cylindrical capacitor is introduced. In other words, there is a problem that the electric tool will have an excessively large size.

### CITATION LIST

### Patent Literature

Patent Literature 1: JP 2004-15986A

### SUMMARY OF INVENTION

An object of the present disclosure is to provide an electric tool designed to reduce an increase in its size.

An electric tool according to an aspect of the present disclosure includes a motor, a plurality of switch elements, a cylindrical capacitor, a circuit board, a housing, and a holder. The plurality of switch elements switches a current flowing through the motor. The capacitor stabilizes the voltage to be applied to the plurality of switch elements. The circuit board mounts the capacitor thereon and is fixed to overlap with at least a part of the motor when viewed in an axial direction defined with respect to a rotary shaft of the motor. The housing houses the motor, the plurality of switch elements, the circuit board, and the capacitor inside. The holder holds a tip tool to which rotational force is transmitted from the motor. The circuit board has a base portion having a shape of a plate and a protruding portion having a shape of a plate. The protruding portion protrudes from an end part of the base portion in a predetermined direction. The capacitor is arranged on the protruding portion to overlap with at least a part of the motor when viewed in a protruding direction that is the predetermined direction in which the protruding portion protrudes.

### BRIEF DESCRIPTION OF DRAWINGS

FIG. 1 is a cross-sectional view of a main part of an electric tool according to an embodiment;

FIG. 2 is a block diagram illustrating a schematic configuration for the electric tool;

FIG. 3 is a cross-sectional view of a main part of the electric tool; and

FIG. 4 is a perspective view illustrating the appearance of the electric tool.

### DESCRIPTION OF EMBODIMENTS

### Embodiment

### (1) Overview

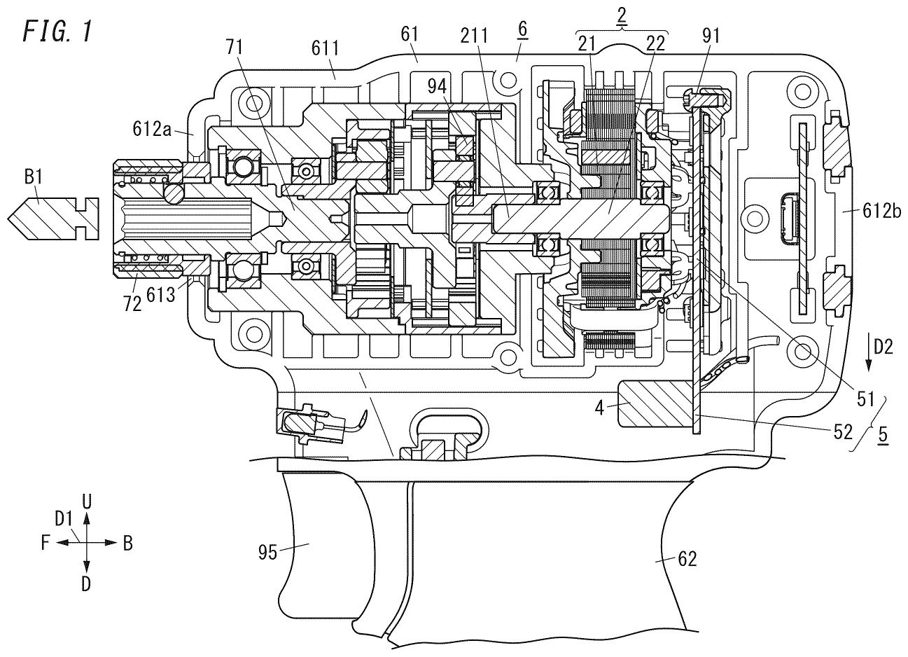

An overview of an electric tool 1 according to an exemplary embodiment will now be described with reference to FIGS. 1-3.

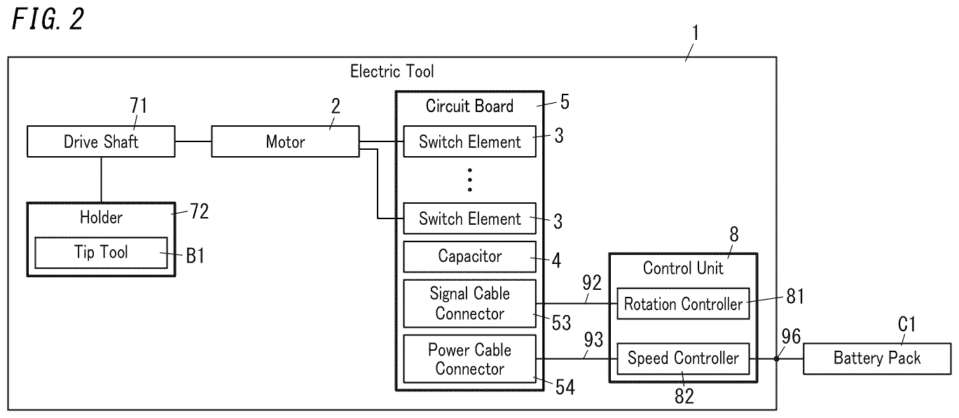

The electric tool 1 according to this embodiment includes, as shown in FIGS. 1 and 2, a motor 2, a plurality of switch elements 3, a cylindrical capacitor 4 (hereinafter simply referred to as a “capacitor 4”), a circuit board 5, a housing 6, and a holder 72. The electric tool 1 is supposed to be an electric screwdriver to be used by a worker to perform fastening operations including tightening a fastening member (such as a screw, a bolt, or a nut) into a work target (such as an electrical appliance or a piece of furniture). Alternatively, the electric tool 1 may also be an electric screwdriver to be used by the worker to perform disassembling operations including loosening a fastening member from the work target.

The plurality of switch elements 3 switches a current flowing through the motor 2. The cylindrical capacitor 4 stabilizes the voltage to be applied to the plurality of switch elements 3. The capacitor 4 is disposed on the circuit board 5. The circuit board 5 is fixed to the housing 6 to overlap with at least a part of the motor 2 when viewed in an axial direction D1 defined with respect to a rotary shaft of the motor 2. The housing 6 houses the motor 2, the circuit board 5, and the capacitor 4. The holder 72 holds a tip tool B1 to which rotational force is transmitted from the motor 2.

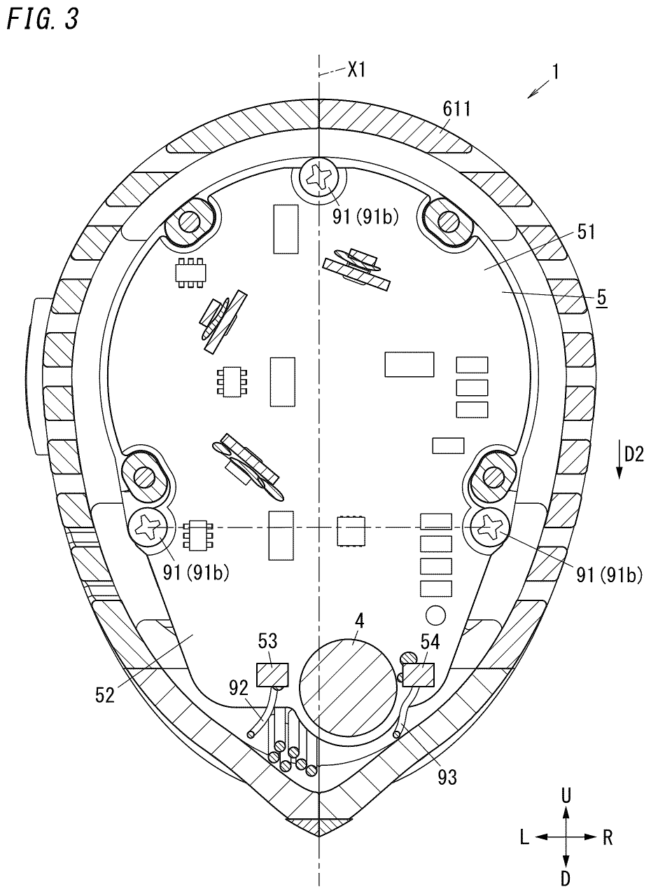

The circuit board 5 has a base portion 51 and a protruding portion 52 as shown in FIG. 3. The base portion 51 has a plat shape. The protruding portion 52 also has the shape of a plate that protrudes from an end part of the base portion 51 in a predetermined direction.

The capacitor 4 is, as shown in FIG. 1 arranged on the protruding portion 52 to overlap with at least a part of the motor 2 when viewed in a protruding direction D2 (refer to FIG. 3) that is the predetermined direction in which the protruding portion 52 protrudes.

As can be seen from the foregoing description, the electric tool 1 according to this embodiment allows for reducing the size of the housing 6 in the axial direction D1 compared with an electric tool in which a capacitor is arranged on a circuit board not to overlap with a motor when viewed in the protruding direction D2. In other words, the electric tool 1 according to this embodiment has the advantage of reducing the degree of an increase in its size. As a result, the electric tool 1 also has the advantage of improving its handiness for the worker who performs fastening or disassembling operations.

### (2) Detailed Configuration

### (2-1) Overall Configuration

Next, a detailed configuration for the electric tool 1 according to this embodiment will be described with reference to FIGS. 1 to 4.

The electric tool 1 includes, as shown in FIGS. 1 to 3, the motor 2, the switch elements 3, the capacitor 4, the circuit board 5, the housing 6, a drive shaft 71, the holder 72, and a control unit 8. The electric tool 1 further includes, in addition to these constituent elements, a plurality of fastening members 91, a signal cable 92, a power cable 93, a planetary gear mechanism 94, an operating member 95, and a battery terminal 96.

In the following description, as shown in FIG. 1, a direction in which the motor 2 and the holder 72 are arranged side by side will be herein defined to be a “forward/backward direction.” One direction pointing from the motor 2 toward the holder 72 is herein defined to be the “forward direction,” and the other direction pointing from the holder 72 toward the motor 2 is herein defined to be the “backward direction.” Also, in the following description, as shown in FIG., the direction in which a body 61 (to be described later) and a grip 62 (to be described later) are arranged one on top of the other is herein defined to be an “upward/downward direction.” One direction pointing from the grip 62 toward the body 61 is herein defined to be the “upward direction,” and the other direction pointing from the body 61 toward the grip 62 is herein defined to be the “downward direction.” In addition, the direction perpendicular to the forward/backward direction and the upward/downward direction is herein defined to be a “rightward/leftward direction.” However, these definitions should not be construed as defining the direction in which the electric tool 1 is supposed to be used.

### (2-2) Housing

The housing 6 houses the motor 2, the capacitor 4, the circuit board 5, and at least a part of the drive shaft 71.

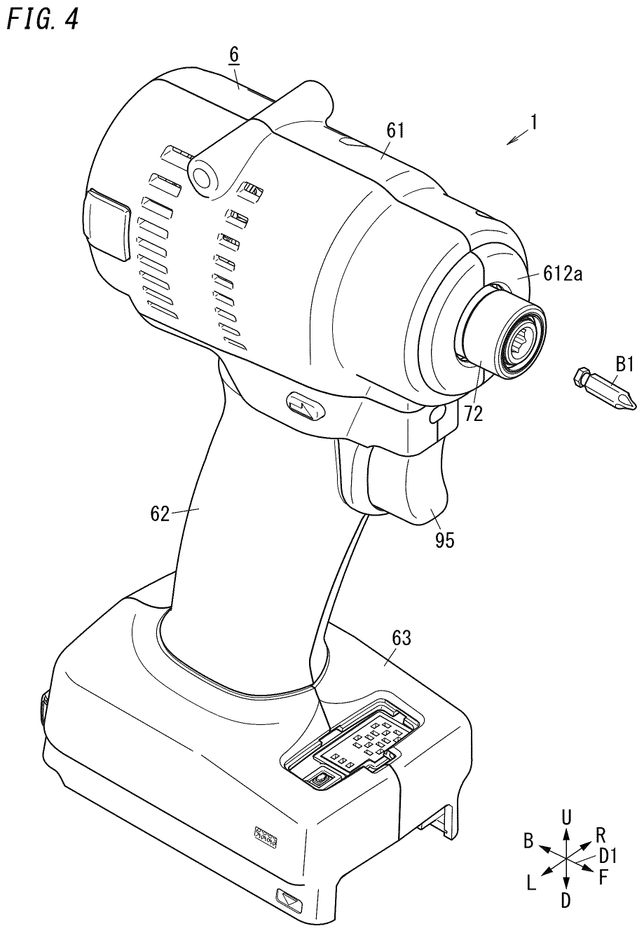

The housing 6 has, as shown in FIG. 4, the body 61, the grip 62, and a battery attachment 63.

### (Body)

The body 61 houses, as shown in FIG. 1, the motor 2, the capacitor 4, the circuit board 5, and at least a part of the drive shaft 71.

The body 61 has a side portion 611 and two bottom portions 612a and 612b. The side portion 611 has the shape of a cylinder. More specifically, the side portion 611 has a circular cylindrical shape. Each of the two bottom portions 612a and 612b is arranged to cover a corresponding one of the openings formed through the cylindrical side portion 611 in the forward/backward direction. That is to say, the body 61 is a bottomed cylinder. The two bottom portions 612a and 612b have a disk shape. The thickness of the two bottom portions 612a and 612b is aligned with the forward/backward direction. The bottom portion 612a, which is one of the two bottom portions 612a and 612b, has a through hole 613. In this embodiment, the through hole 613 is provided through a central part of the bottom portion 612a. The drive shaft 71 is passed through the through hole 613.

### (Grip)

The grip 62 protrudes from the body 61. More specifically, the grip 62 protrudes, as shown in FIG. 4, downward from the body 61. The worker may perform operations such as fastening a screw by gripping the grip 62.

### (Battery Attachment)

The battery attachment 63 substantially has the shape of a rectangular parallelepiped. The battery attachment 63 is, as shown in FIG. 4, connected to the lower end part of the grip 62. A rechargeable battery pack C1 (refer to FIG. 2) is attached removably to the battery attachment 63. The electric tool 1 is powered by the battery pack C1 as a power supply. That is to say, the battery pack C1 is a power supply that supplies electric power for driving the motor 2. The battery pack C1 is not a constituent element of the electric tool 1. However, this should not be construed as limiting. Alternatively, the electric tool 1 may include the battery pack C1. The battery pack C1 includes an assembled battery formed by connecting a plurality of secondary batteries (such as lithium-ion batteries) in series and a case that houses the assembled battery therein.

A battery terminal 96 (refer to FIG. 2) to be electrically connected to the battery pack C1 when the battery pack C1 is attached to the battery attachment 63 is provided for the battery attachment 63 according to this embodiment. The power cable 93 electrically connects the battery terminal 96 to (a power cable connector 54 (to be described later) of) the circuit board 5 and transmits electric power, supplied from the battery pack C1 to the motor 2, to the circuit board 5. The electric power transmitted to the circuit board 5 is supplied to the motor 2 via the plurality of switch elements 3.

### (2-3) Motor

As shown in FIG. 1, the motor 2 is housed in a rear part of the body 61. The motor 2 includes: a rotor 21 including a rotary shaft 211 and permanent magnets; and a stator 22 including a plurality of coils. The axial direction D1 defined with respect to the rotary shaft 211 is aligned with the forward/backward direction. The rotor 21 rotates with respect to the stator 22 due to electromagnetic interactions between the permanent magnets and the plurality of coils. Specifically, the plurality of switch elements 3 switches a current flowing through each of the plurality of coils, thereby causing the rotor 21 to rotate with respect to the stator 22 due to electromagnetic interactions between the permanent magnets and the coils in which a current flows alternately.

Also, the motor 2 is a servo motor. The torque and rotational speed of the motor 2 vary under the control of the control unit 8 (more specifically, a speed controller 82 thereof (to be described later)). More specifically, the control unit 8 controls the operation of the motor 2 by performing feedback control to control the torque and rotational speed of the motor 2 toward their respective target values.

### (2-4) Circuit Board

The circuit board 5 is a board on which a plurality of electric components for driving the motor 2 are mounted. As used herein, the “plurality of electric components” includes the plurality of switch elements 3 and the capacitor 4. That is to say, the plurality of switch elements 3 and the capacitor 4 are mounted on the circuit board 5. In this embodiment, the plurality of switch elements 3 and the capacitor 4 are mounted on the front surface of the circuit board 5.

The circuit board 5 is, as shown in FIG. 1, housed in the rear part of the body 61. In this embodiment, the circuit board 5 is disposed backward of the motor 2 in the axial direction D1. The circuit board 5 is a plate member. The circuit board 5 is arranged to overlap with at least a part of the motor 2 when viewed in the axial direction D1. In this embodiment, the thickness of the circuit board 5 is aligned with the axial direction D1 (the forward/backward direction).

The circuit board 5 has a base portion 51 and a protruding portion 52. The base portion 51 has the shape of a plate. The base portion 51 according to this embodiment has, when viewed in the axial direction D1, the shape of a circle from which a lower part in the shape of an arc is cut out as shown in FIG. 3. The protruding portion 52 has the shape of a plate that protrudes in a predetermined direction from an end part of the base portion 51. In this embodiment, the protruding portion 52 has the shape of a plate that protrudes in a downward direction from the lower end part of the base portion 51. The protruding direction D2 shown in FIG. 3 is the predetermined direction in which the protruding portion 52 protrudes. The protruding direction D2 according to this embodiment is downward. The protruding portion 52 according to this embodiment has the shape of an isosceles trapezoid that gradually decreases its width (its dimension as measured in the rightward/leftward direction) from up to down when viewed in the axial direction D1.

A plurality of fastening members 91 are used to fasten the base portion 51 to the housing 6. For example, each of the plurality of fastening members 91 is a fastening screw. The plurality of fastening members 91 are inserted into through holes (not shown) provided through the base portion 51 and screwed into respective screw holes of the housing to fix the base portion 51 onto the housing 6.

As shown in FIG. 3, the number of the fastening members 91 according to this embodiment is three. Two fastening members 91a out of the three fastening members 91 are inserted respectively through the left and right sides of the lower end part of the base portion 51. These two fastening members 91a are inserted to face each other in the rightward/leftward direction. These two fastening members 91a are located close to the protruding portion 52.

According to this embodiment, the two fastening members 91a are respectively inserted through the lower left and lower right portions of the base portion 51. In other words, these two fastening members 91a are inserted through an outer edge portion at the lower end part of the base portion 51. As used herein, the term “outer” refers to a direction pointing away from the center of the base portion 51 as a reference point. The two fastening members 91a are inserted through the lower end part of the base portion 51 to be as distant from each other as possible in the rightward/leftward direction. This configuration achieves the advantage of allowing the circuit board 5 to be fixed more stably to the housing 6.

On the other hand, the remaining fastening member 91b out of the three fastening members 91 is inserted through a middle part at the upper end part of the base portion 51 in the rightward/leftward direction.

### (Switch Element)

The plurality of switch elements 3 switches the current flowing through the motor 2. More specifically, the plurality of switch elements 3 are provided one to one for the plurality of coils of the motor 2. Each of the plurality of switch elements 3 selectively allows the current to flow through a corresponding one of the coils. Each of the plurality of switch elements 3 is, for example, FET (field effect transistor) element. The circuit board 5 is an FET board.

The plurality of switch elements 3 according to this embodiment are arranged on the same circuit board 5 as the capacitor 4. More specifically, the plurality of switch elements 3 are arranged on the base portion 51 of the circuit board 5. According to this configuration, there is no need for the electric tool 1 to be provided with an extra board apart from the circuit board 5 to mount the plurality of switch elements 3 thereon. As a result, the electric tool 1 according to this embodiment may advantageously have a smaller size than an electric tool including, apart from the circuit board 5, an additional board on which the plurality of switch elements 3 are arranged.

### (Capacitor)

The capacitor 4 stabilizes the voltage to be applied to the plurality of switch elements 3. More specifically, a cable that electrically connects the power cable connector 54 (to be described later) and the plurality of switch elements 3 is arranged to run through the capacitor 4, thus allowing the capacitor 4 to stabilize the voltage to be applied to the plurality of switch elements 3.

The capacitor 4 according to this embodiment has a circular cylindrical shape. In general, a circular cylindrical capacitor tends to have a larger electric capacitance than a chip capacitor. Therefore, the circular cylindrical capacitor 4 further stabilizes the voltage to be applied to the plurality of switch elements 3.

The capacitor 4 is mounted on the circuit board 5 so that the axial direction defined with respect to the capacitor 4 is aligned with the thickness of the circuit board 5 (i.e., the forward/backward direction). In other words, the capacitor 4 is mounted on the circuit board 5 so that radial direction defined with respect to the capacitor 4 is aligned with the plane direction defined on the front surface of the circuit board 5. In this embodiment, the capacitor 4 is the circular cylindrical capacitor, and therefore, has a larger dimension as measured along the thickness of the circuit board 5 than any other electric component mounted on the circuit board 5.

The capacitor 4 is, as shown in FIG. 1, arranged on the protruding portion 52 so that a front part of the capacitor 4 overlaps with a rear part of the motor 2 when viewed in the protruding direction D2. In other words, the front part of the capacitor 4 overlaps with the rear part of the motor 2 when viewed in the protruding direction D2. According to this configuration, the electric tool 1 according to this embodiment allows for reducing the dimension of the housing 6 in the axial direction D1 compared with an electric tool in which a capacitor is arranged on a circuit board not to overlap with a motor when viewed in the protruding direction D2. That is to say, the electric tool 1 according to this embodiment has the advantage of reducing the degree of increase in its size. As a result, the electric tool 1 also has the advantage of improving its handiness for the worker who performs fastening or disassembling operations.

Also, the capacitor 4 is, as shown in FIG. 3, disposed between the two fastening members 91a out of the three fastening members 91 when viewed in the protruding direction D2. This configuration achieves the advantage of reducing the chances of the stress, caused to the circuit board 5 by the vibration of the motor 2, concentrating on one of the two fastening members 91a due to the load of the capacitor 4. As a result, this configuration achieves the advantage of improving the durability of the circuit board 5.

Note that it is preferable that the capacitor 4 be disposed on the protruding portion 52 so that at least a part of the capacitor 4 overlaps with the vertical bisector X1 of a line segment connecting the two fastening members 91a when viewed along the thickness of the base portion 51 (i.e., the forward/backward direction according to this embodiment). This configuration achieves the advantage of distributing the stress, caused to the circuit board 5 by the vibration of the motor 2, substantially equally to the two fastening members 91a. That is to say, this configuration achieves the advantage of improving the durability of the circuit board 5 more significantly. The vertical bisector X1 as shown in FIG. 3 is a virtual line. As used herein, “at least a part of the capacitor 4 overlaps with the vertical bisector X1 of the line segment connecting the two fastening members 91a” means that the vertical bisector X1 passes through at least a part of the capacitor 4.

Note that, to achieve the advantage of reducing the concentration of the stress, the vertical bisector X1 more preferably passes through the center of gravity of the capacitor 4 when viewed along the thickness of the base portion 51. However, the vertical bisector X1 passes, according to this embodiment, through a part on the left of the center of the gravity of the capacitor 4, as shown in FIG. 3, when viewed from in front of the base portion 51 due to the design constraints on the electric tool 1.

### (Signal Cable Connector and Power Cable Connector)

The circuit board 5 includes a signal cable connector 53 and a power cable connector 54.

The signal cable connector 53 receives a signal cable 92 (to be described later) connected thereto. The signal cable connector 53 is electrically connected to the plurality of switch elements 3 via wiring provided on the circuit board 5. Thus, a control signal transmitted to the signal cable connector 53 through the signal cable 92 is transmitted to the plurality of switch elements 3 via the wiring.

In the same way, the power cable connector 54 receives a power cable 93 connected thereto. The power cable connector 54 is electrically connected to the plurality of switch elements 3 via the wiring provided on the circuit board 5. Thus, the electric power transmitted to the power cable connector 54 through the power cable 93 is transmitted to the plurality of switch elements 3 via the wiring and the capacitor 4. Then the plurality of switch elements 3 selectively supplies the electric power thus transmitted to the plurality of coils of the motor 2 one after another.

The signal cable connector 53 and the power cable connector 54 are, as shown in FIG. 3, arranged on both sides of the capacitor 4 on the protruding portion 52. In other words, the signal cable connector 53 and the power cable connector 54 are arranged to interpose the capacitor 4 between themselves and to be adjacent to the capacitor 4 on both sides. This configuration achieves the advantage of reducing the chances of the electromagnetic noise emitted from the power cable 93 arriving at the signal cable 92, because the capacitor 4 allows for easily absorbing the electromagnetic noise. As a result, this configuration achieves the advantage of reducing the chances of causing an inconvenience that the electromagnetic noise emitted from the power cable 93 interferes with the function of the signal cable 92.

In this embodiment, the signal cable connector 53 and the power cable connector 54 are arranged to face each other in the rightward/leftward direction with respect to the capacitor 4. When viewed from in front of the circuit board 5, the signal cable connector 53 is disposed on the left side of the capacitor 4 and the power cable connector 54 is disposed on the right side of the capacitor 4. However, this should not be construed as limiting. Alternatively, the signal cable connector 53 may also be disposed on the right side of the capacitor 4 and the power cable connector 54 may also be disposed on the left side of the capacitor 4.

### (2-5) Drive Shaft

The drive shaft 71 is connected to the rotary shaft 211 via a planetary gear mechanism 94. As a result, the drive shaft 71 rotates synchronously as the rotary shaft 211 of the motor 2 rotates. That is to say, the drive shaft 71 is caused to rotate by the motor 2.

The planetary gear mechanism 94 transforms the rotational speed and torque of the rotary shaft 211 of the motor 2 into the rotational speed and torque which are required for screwing operations. The planetary gear mechanism 94 is a speed reducer. The torque of the rotary shaft 211 of the motor 2 is transmitted to the drive shaft 71 via the planetary gear mechanism 94.

### (2-6) Holder

The holder 72 holds a tip tool B1 to which rotational force is transmitted from the motor 2. The holder 72 is provided at a front end of the drive shaft 71. The drive shaft 71 is caused to rotate, along with the tip tool B1, by the motor 2.

In this embodiment, the holder 72 is provided so that the tip tool B1 (refer to FIGS. 1 and 2) is removably attached to the holder 72 via a chuck. However, this should not be construed as limiting. Alternatively, the tip tool B1 may also be removably attached to the holder 72 directly without using the chuck. Still alternatively, the tip tool B1 may form an integral part of the holder 72. The tip tool B1 is, for example, a screwdriver bit. Turning the tip tool B1 engaged with a fastening member allows the operations of either tightening or loosening the fastening member to be performed.

### (2-7) Operating Member

As shown in FIG. 4, an operating member 95 protrudes from the grip 62. The operating member 95 accepts an operating command to control the rotation of the rotary shaft 211 of the motor 2. Pulling the operating member 95 allows the motor 2 to be selectively turned ON and OFF. Also, the rotational speed of rotary shaft 211 may be adjusted depending on how deep the operating member 95 is pulled. The deeper the operating member 95 is pulled, the higher the rotational speed of the rotary shaft 211 becomes.

### (2-8) Control Unit

The control unit 8 includes, as shown in FIG. 2, a rotation controller 81 and a speed controller 82.

The rotation controller 81 controls the plurality of switch elements 3 by selectively supplying electric power from the battery pack C1 to one of the plurality of coils of the motor 2 after another, thereby controlling the rotation of the motor 2. The rotation controller 81 controls the plurality of switch elements 3 based on the angle of rotation of the rotor 21. For example, the motor 2 includes a magnetic sensor (not shown) for detecting the magnetic field generated by permanent magnets of the rotor 21. The rotation controller 81 controls the plurality of switch elements 3 based on the angle of rotation of the rotor 21 calculated from the detected result of the above-described magnetic sensor.

The rotation controller 81 outputs a control signal indicating the specifics of control to the plurality of switch elements 3 on the circuit board 5 via the signal cable 92 (refer to FIG. 2). The signal cable 92 electrically connects the rotation controller 81 and (the signal cable connector 53 of) the circuit board 5, and transmits the control signal indicating the specifics of control of the rotation controller 81 to (the plurality of switch elements 3 of) the circuit board 5.

The speed controller 82 either starts or stops rotating the rotary shaft of the motor 2 depending on how deep the operating member 95 is pulled. In addition, the speed controller 82 also controls the rotation speed of the rotary shaft 211.

The speed controller 82 includes, for example, a microcontroller. The speed controller 82 may change the rotation speed of the drive shaft 71 and the tip tool B1 by changing the rotation speed of the rotary shaft 211. The speed controller 82 is, for example, disposed on the power cable 93 and changes the electric power, supplied from the battery pack C1 to the motor 2 via the plurality of switch elements 3, thereby changing the rotation speed of the rotary shaft 211.

### (3) Variation

Next, variations of the exemplary embodiment will be enumerated one after another. Note that the variations to be described below may be adopted in combination as appropriate.

In the above-described embodiment, the base portion 51 has, when viewed in the axial direction D1, the shape of a circle from which a lower part in the shape of an arc is cut out. However, this should not be construed as limiting. Alternatively, the base portion 51 may also have the shape of a rectangle, a circle, or an ellipse. In other words, the shape of the base portion 51 when viewed in the axial direction D1 is not limited to any particular shape.

The shape of the protruding portion 52 is, when viewed in the axial direction D1, an isosceles trapezoid in the above-described embodiment, but may also be a rectangle or a triangle that gradually decreases its width (i.e., its dimension as measured in the rightward/leftward direction) from up to down. In other words, the shape of the protruding portion 52 is not limited to any particular shape when viewed in the axial direction D1.

In addition, in the above-described embodiment, the protruding portion 52 has the shape of a plate that protrudes in the downward direction from the lower end part of the base portion 51. However, this should not be construed as limiting. Alternatively, the protruding portion 52 may also have the shape of a plate that protrudes in the upward direction from the upper end part of the base portion 51. Still alternatively, the protruding portion 52 may also have the shape of a plate that protrudes in the leftward direction from the left end part of the base portion 51 or may also have the shape of a plate that protrudes in the rightward direction from the right end part of the base portion 51. In other words, the protruding direction D2 in which the protruding portion 52 protrudes is the downward direction in the above-described embodiment, but may also be the upward, leftward, or rightward direction.

Note that the protruding portion 52 may have the shape of a plate that protrudes diagonally to the lower left (or diagonally to the lower right, the upper left, or the upper right) from a lower left end (or lower right end, upper left end, or upper right end) part of the base portion 51. In other words, the protruding direction D2 in which the protruding portion 52 protrudes may be diagonally downward to the left (or diagonally downward to the right, diagonally upward to the left, or diagonally upward to the right). That is to say, the protruding direction D2 in which the protruding portion 52 protrudes may be any direction that intersects with the axial direction D1 defined with respect to the rotary shaft 211 (i.e., the forward/backward direction).

Also, the protruding portion 52 may have the shape of a plate that protrudes diagonally downward to the left or to the right from the lower end part of the base portion 51.

In the above-described embodiment, the number of the fastening members 91 is three. However, this should not be construed as limiting. The number of the fastening members 91 may be two or equal to or greater than four. In other words, the number of the fastening members 91 only needs to be equal to or greater than two.

Also, in the above-described embodiment, each of the two fastening members 91a is inserted through the outer edge portion at the lower end part of the base portion 51. Alternatively, each of the two fastening members 91a may also be inserted inside the outer edge portion at the lower end part of the base portion 51. As used herein, the “inside” refers to a direction pointing toward the middle of the line segment defined with respect to the base portion 51.

Also, in the above-described embodiment, the two fastening members 91a are respectively inserted through the lower left end part and the lower right end part of the base portion 51. However, this should not be construed as limiting. Alternatively, the left fastening member 91a of these two fastening members 91a may also be inserted through a part on the right side of the lower left end part of the base portion 51, and the right fastening member 91a may also be inserted through a part on the left side of the lower right end part of the base portion 51. That is to say, the two fastening members 91a do not have to be inserted through the lower end part of the base portion 51 to be as distant from each other as possible in the rightward/leftward direction.

In the above-described embodiment, the two fastening members 91a are inserted to face each other in the rightward/leftward direction. However, the two fastening members 91a do not have to be inserted to face each other in the rightward/leftward direction. Alternatively, one of the two fastening members 91a may also be inserted through a lower part of the base portion 51 than the other fastening members 91a.

Also, in the above-described embodiment, each of the two fastening members 91a is inserted through the base portion 51. However, this should not be construed as limiting. Alternatively, each of the two fastening members 91a may also be inserted through the protruding portion 52. For example, one of the two fastening members 91a may also be inserted through a left part of the protruding portion 52, while the other fastening member 91a may also be inserted through a right part of the base portion 51. Conversely, one of the two fastening members 91a may also be inserted through a right part of the protruding portion 52, while the other fastening member 91a may also be inserted through a left part of the base portion 51.

In the above-described embodiment, the plurality of switch elements 3 are mounted on the same circuit board 5 as the capacitor 4. However, this should not be construed as limiting. Alternatively, the plurality of switch elements 3 may also be mounted on a different board provided separately from the circuit board 5. That is to say, the electric tool 1 may include an additional board, apart from the circuit board 5, to mount the plurality of switch elements 3 on the additional board.

In the above-described embodiment, the capacitor 4 is a circular cylindrical capacitor (i.e., having a circular shape when viewed in the axial direction defined with respect to the capacitor 4). However, this should not be construed as limiting. Alternatively, the capacitor 4 may also have the shape of a polygon (e.g., a quadrangle or a pentagon) when viewed in the axial direction defined with respect to the capacitor 4. Still alternatively, the capacitor 4 may also have the shape of a polygon with round corners when viewed in the axial direction defined with respect to the capacitor 4. That is to say, the shape of the capacitor 4 is not limited to any particular shape when viewed in the axial direction defined with respect to the capacitor 4.

The above-described electric tool 1 is an electric screwdriver to be used by a worker to perform either fastening operations including tightening a fastening member into a work target, or disassembling operations including loosening a fastening member from a work target. However, this should not be construed as limiting. Alternatively, the electric tool 1 may also be a drill driver, a hammer drill, a band saw machine, a power cutter, an electric sander, or a disc grinder.

Also, the electric tool 1 may also be an impact screwdriver or an impact wrench.

### (Recapitulation)

An electric tool (1) according to a first aspect includes a motor (2), a plurality of switch elements (3), a cylindrical capacitor (4), a circuit board (5), a housing (6), and a holder (72). The plurality of switch elements (3) switches a current flowing through the motor (2). The capacitor (4) stabilizes the voltage to be applied to the plurality of switch elements (3). The circuit board (5) mounts the capacitor (4) thereon and is fixed to overlap with at least a part of the motor (2) when viewed in an axial direction (D1) defined with respect to a rotary shaft (211) of the motor (2). The housing (6) houses the motor (2), the plurality of switch elements (3), the circuit board (5), and the capacitor (4) inside. The holder (72) holds a tip tool (B1) to which rotational force is transmitted from the motor (2). The circuit board (5) has a base portion (51) having a shape of a plate and a protruding portion (52) having a shape of a plate. The protruding portion (52) protrudes from an end part of the base portion (51) in a predetermined direction. The capacitor (4) is arranged on the protruding portion (52) to overlap with at least a part of the motor (2) when viewed in a protruding direction (D2) that is the predetermined direction in which the protruding portion (52) protrudes.

This aspect has the advantage of reducing the degree of an increase in the size of the electric tool (1).

An electric tool (1) according to a second aspect, which may be implemented in conjunction with the first aspect, further includes a plurality of fastening members (91). The plurality of fastening members (91) is used to fix the base portion (51) onto the housing (6). The capacitor (4) is interposed between two fastening members (91a) out of the plurality of fastening members (91) when viewed in the protruding direction (D2). The two fastening members (91a) are located closer to the protruding portion (52) than at least another fastening member (91) belonging to the plurality of fastening members (91).

This aspect achieves the advantage of improving the durability of the circuit board (5).

In an electric tool (1) according to a third aspect, which may be implemented in conjunction with the second aspect, the capacitor (4) is disposed on the protruding portion (52) so that at least a part of the capacitor (4) overlaps with the vertical bisector (X1) of a line segment connecting the two fastening members (91) together when viewed along the thickness of the base portion (51).

This aspect achieves the advantage of improving the durability of the circuit board (5) more significantly.

In an electric tool (1) according to a fourth aspect, which may be implemented in conjunction with any one of the first to third aspects, the plurality of switch elements (3) are mounted on the circuit board (5).

This aspect achieves the advantage of reducing the size of the electric tool (1).

An electric tool (1) according to a fifth aspect, which may be implemented in conjunction with the fourth aspect, further includes a rotation controller (81), a signal cable (92), and a power cable (93). The rotation controller (81) controls the plurality of switch elements (3). The signal cable (92) transmits a control signal indicating specifics of control of the rotation controller (81) to the circuit board (5). The power cable (93) transmits electric power to be supplied to the motor (2) to the circuit board (5). The circuit board (5) further includes a signal cable connector (53) and a power cable connector (54). The signal cable connector (53) receives the signal cable (92) connected thereto. The power cable connector (54) receives the power cable (93) connected thereto. The signal cable connector (53) and the power cable connector (54) are arranged on both sides of the capacitor (4) on the protruding portion (52).

This aspect achieves the advantage of reducing the chances of causing an inconvenience that the electromagnetic noise emitted from the power cable (93) interferes with the function of the signal cable (92).

### REFERENCE SIGNS LIST

1 Electric Tool
2 Motor
21 Rotor
211 Rotary Shaft
22 Stator
3 Switch Element
4 Capacitor
5 Circuit Board
51 Base Portion
52 Protruding Portion
53 Signal Cable Connector
54 Power Cable Connector
6 Housing
61 Body
611 Side Portion
612a, 612b Bottom Portion
613 Through Hole
62 Grip
63 Battery Attachment
71 Drive Shaft
72 Holder
8 Control Unit
81 Rotation Controller
82 Speed Controller
91 (91a) Fastening Member
92 Signal Cable
93 Power Cable
94 Planetary Gear Mechanism
95 Operating Member
96 Battery Terminal
B1 Tip Tool
C1 Battery Pack
D1 Axial Direction
D2 Protruding Direction
X1 Vertical Bisector

1. An electric tool comprising:
a motor;
a plurality of switch elements configured to switch a current flowing through the motor;
a capacitor configured to stabilize a voltage to be applied to the plurality of switch elements, the capacitor having a cylindrical shape;
a circuit board mounting the capacitor thereon and fixed to overlap with at least a part of the motor when viewed in an axial direction defined with respect to a rotary shaft of the motor;
a housing arranged to house the motor, the plurality of switch elements, the circuit board, and the capacitor inside; and
a holder arranged to hold a tip tool to which rotational force is transmitted from the motor;
the circuit board including:
a base portion having a plat shape; and
a protruding portion having a shape of a plate which protrudes from an end part of the base portion in a predetermined direction, and
the capacitor being arranged on the protruding portion to overlap with at least a part of the motor when viewed in a protruding direction that is the predetermined direction in which the protruding portion protrudes.

2. The electric tool of claim 1, further comprising a plurality of fastening members configured to fix the base portion onto the housing, wherein
the capacitor is interposed between two fastening members out of the plurality of fastening members when viewed in the protruding direction, the two fastening members being located closer to the protruding portion than at least another fastening member belonging to the plurality of fastening members.

3. The electric tool of claim 2, wherein
the capacitor is disposed on the protruding portion so that at least a part of the capacitor overlaps with a vertical bisector of a line segment connecting the two fastening members together when viewed along thickness of the base portion.

4. The electric tool of claim 1, wherein
the plurality of switch elements are mounted on the circuit board.

5. The electric tool of claim 4, further comprising:
a rotation controller configured to control the plurality of switch elements;
a signal cable configured to transmit a control signal indicating specifics of control of the rotation controller to the circuit board; and
a power cable configured to transmit electric power to be supplied to the motor to the circuit board, wherein
the circuit board further includes:
a signal cable connector configured to receive the signal cable connected thereto; and
a power cable connector configured to receive the power cable connected thereto,
the signal cable connector and the power cable connector are arranged on both sides of the capacitor on the protruding portion.

6. The electric tool of claim 2, wherein
the plurality of switch elements are mounted on the circuit board.

7. The electric tool of claim 6, further comprising:
a rotation controller configured to control the plurality of switch elements;
a signal cable configured to transmit a control signal indicating specifics of control of the rotation controller to the circuit board; and
a power cable configured to transmit electric power to be supplied to the motor to the circuit board, wherein
the circuit board further includes:
a signal cable connector configured to receive the signal cable connected thereto; and
a power cable connector configured to receive the power cable connected thereto,
the signal cable connector and the power cable connector are arranged on both sides of the capacitor on the protruding portion.

8. The electric tool of claim 3, wherein
the plurality of switch elements are mounted on the circuit board.

9. The electric tool of claim 8, further comprising:
a rotation controller configured to control the plurality of switch elements;
a signal cable configured to transmit a control signal indicating specifics of control of the rotation controller to the circuit board; and
a power cable configured to transmit electric power to be supplied to the motor to the circuit board, wherein
the circuit board further includes:
a signal cable connector configured to receive the signal cable connected thereto; and
a power cable connector configured to receive the power cable connected thereto,
the signal cable connector and the power cable connector are arranged on both sides of the capacitor on the protruding portion.
